(19) United States
(12) Patent Application Publication
(10) Pub. No.: US 2014/0154406 A1
(43) Pub. Date: Jun. 5, 2014

(54) WET ACTIVATION OF RUTHENIUM CONTAINING LINER/BARRIER

(71) Applicant: LAM RESEARCH CORPORATION, Fremont, CA (US)

(72) Inventors: Yezdi Dordi, Palo Alto, CA (US); Dries Dictus, Kessel-Lo (BE)

(73) Assignee: LAM RESEARCH CORPORATION, Fremont, CA (US)

(21) Appl. No.: 13/691,436

(22) Filed: Nov. 30, 2012

(51) Int. Cl. H01L 21/02

(52) U.S. Cl. CPC H01L 21/02002
USPC 427/98.6; 118/612; 134/36; 134/29; 134/100.1

(57) ABSTRACT

Methods and systems are provided for preparing a ruthenium containing liner/barrier for metal deposition, and are useful in the manufacture of integrated circuits. In accordance with one embodiment, a borohydride solution having a pH greater than 12 is mixed with DI water at the place of application to form a pretreatment solution. The pretreatment solution is applied to reduce a ruthenium-containing surface of a substrate. Following reduction of the ruthenium containing surface, copper deposition may be initiated.

### BACKGROUND

In the fabrication of semiconductor devices such as integrated circuits, memory cells, and the like, a series of manufacturing operations are performed to define features on semiconductor wafers (“wafers”). The wafers (or substrates) include integrated circuit devices in the form of multi-level structures defined on a silicon substrate. At a substrate level, transistor devices with diffusion regions are formed. In subsequent levels, interconnect metallization lines are patterned and electrically connected to the transistor devices to define a desired integrated circuit device. Also, patterned conductive layers are insulated from other conductive layers by dielectric materials.

At present, ruthenium (Ru) is gaining attention as a base for fine copper wiring in semiconductors and as a material for use in dynamic random access memory (DRAM) capacitor electrodes. A sub-30 nanometer circuit line width has been achieved in the progressively miniaturized semiconductor market, and it is hoped that mass production of sub-20-nanometer next-generation semiconductors and eventually sub-10-nanometer mass production will be realized.

An aspect for realizing fine wiring utilizing sub-10-nanometer processes is improvement in the embedding of copper plating. One method for improving the embedding of copper platting entails deposition of a thin layer of ruthenium as a base for copper plating. Ruthenium is suitable as a base for copper due to its low resistance and excellent compatibility with copper. Various deposition technologies such as chemical vapor deposition CVD), atomic layer deposition (ALD), and electroless deposition, utilizing a variety of ruthenium precursors, may be employed to deposit ruthenium. However, challenges remain in implementing ruthenium deposition on a mass production scale.

It is in this context that embodiments of the invention arise.

### SUMMARY OF THE INVENTION

Broadly speaking, the present invention fills these needs by providing a method for pretreatment of a ruthenium-containing liner/barrier, prior to metal deposition. Several inventive embodiments of the present invention are described below.

In one embodiment, a wet pretreatment method for preparing a ruthenium surface for metal deposition is provided. The method initiates with receiving a borohydride solution having a pH greater than about 12, and receiving deionized (DI) water. The borohydride solution is mixed with the DI water to form a pretreatment solution. The pretreatment solution is applied to the ruthenium surface.

In one embodiment, after applying the pretreatment solution, rinsing the ruthenium surface with DI water.

In one embodiment, the borohydride solution includes a base selected from the group consisting of sodium hydroxide, potassium hydroxide, ammonium hydroxide, trimethylammonium hydroxide, triethylammonium hydroxide.

In one embodiment, the borohydride solution has a borohydride concentration approximately equal to a concentration of the base.

In one embodiment, the borohydride solution has a borohydride concentration of about 0.5 to 2.5 molar (M).

In one embodiment, the pretreatment solution has a borohydride concentration of about 50 to about 2500 millimolar (mM).

In one embodiment, the DI water is degassed DI water having an oxygen concentration of less than about 5 ppb.

In one embodiment, the method is used to perform at least one operation in the fabrication of an integrated circuit.

In another embodiment, a wet pretreatment method for preparing a ruthenium surface for metal deposition is provided. The method includes applying a stream of DI water onto a ruthenium surface. A borohydride solution is mixed into the stream of DI water, the borohydride solution having a pH greater than about 12 prior to the mixing. After a predefined period of time, the mixing of the borohydride solution into the stream of DI water is halted.

In one embodiment, the mixing of the borohydrde solution into the stream of DI water defines a pretreatment operation, and the halting of the mixing of the borohydride solution into the stream of DI water defines initiation of a rinse operation.

In one embodiment, the borohydride solution includes a base selected from the group consisting of sodium hydroxide, potassium hydroxide, ammonium hydroxide, trimethylammonium hydroxide, triethylammonium hydroxide.

In one embodiment, the borohydride solution has a borohydride concentration approximately equal to a concentration of the base.

In one embodiment, the borohydride solution has a borohydride concentration of about 0.5 to 2.5 M.

In one embodiment, the mixing of the borohydride solution into the DI water stream defines a pretreatment solution having a borohydride concentration of about 50 to about 2500 mM.

In one embodiment, the DI water is degassed DI water having an oxygen concentration of less than about 5 ppb.

In one embodiment, after the halting of the mixing of the borohydride solution into the DI water stream, an electroless copper deposition solution is mixed into the DI water stream.

In one embodiment, the method is used to perform at least one operation in the fabrication of an integrated circuit.

In another embodiment, a system for preparing a ruthenium surface of a wafer is provided. The system includes a chamber configured to support the wafer. A DI water source is provided. A conduit is provided for delivering a DI water stream from the DI water source to the chamber for application onto the ruthenium surface of the wafer. A borohydride solution source contains a borohydride solution having a pH greater than 12. A mixer is provided for mixing the borohydride solution from the borohydride solution source into the DI water stream.

In one embodiment, the borohydride solution has a borohydride concentration of about 0.5 to 2.5 M.

In one embodiment, the mixing of the borohydride solution into the DI water stream defines a pretreatment solution having a borohydride concentration of about 50 to about 2500 mM.

In one embodiment, a controller is configured to control the mixer to initiate the mixing of the borohydride solution into the DI water stream and terminate the mixing after a predefined time period has elapsed.

In one embodiment, an electroless copper deposition solution source is provided, and a second mixer is provided for mixing electroless copper deposition solution from the electroless copper deposition solution source into the DI water stream.

In one embodiment, the system is configured to perform at least one operation in the fabrication of an integrated circuit.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

The present invention will be readily understood by the following detailed description in conjunction with the accompanying drawings. To facilitate this description, like reference numerals designate like structural elements.

FIG. 1A illustrates a cross-section view of a portion of a substrate following ruthenium deposition, in accordance with an embodiment of the invention.

FIG. 1B illustrates a substrate following application of a reducing agent to reduce ruthenium oxide to ruthenium, in accordance with an embodiment of the invention.

FIG. 1C illustrates a substrate after deposition of a copper layer over a ruthenium layer has taken place.

FIG. 2 illustrates a method for preparing a ruthenium surface for metal deposition, in accordance with an embodiment of the invention.

FIG. 3 illustrates a system for performing wet processing of a substrate, in accordance with an embodiment of the invention.

FIG. 4 is a graph illustrating the flow of various liquids during reduction and plating processes, in accordance with an embodiment of the invention.

FIG. 5 is a graph conceptually illustrating the rate of borohydride hydrolysis in the presence of Ru as a function of borohydride concentration, in accordance with an embodiment of the invention.

FIG. 6 is a graph conceptually illustrating the concentration of borohydride in a concentrated pretreatment solution over time, in accordance with an embodiment of the invention.

FIG. 7 is a graph illustrating adjustment of the dilution ratio of concentrated pretreatment solution to DI water over time, in accordance with an embodiment of the invention.

FIG. 8 illustrates a method for utilizing a pretreatment solution having non-matching molar concentrations of borohydride and alkaline salts, in accordance with an embodiment of the invention.

### DETAILED DESCRIPTION OF THE PREFERRED EMBODIMENTS

Several embodiments for the prevention of particle adders when contacting a liquid meniscus over a substrate are now described. It will be obvious, however, to one skilled in the art, that the present invention may be practiced without some or all of these specific details. In other instances, well known process operations have not been described in detail in order not to unnecessarily obscure the present invention.

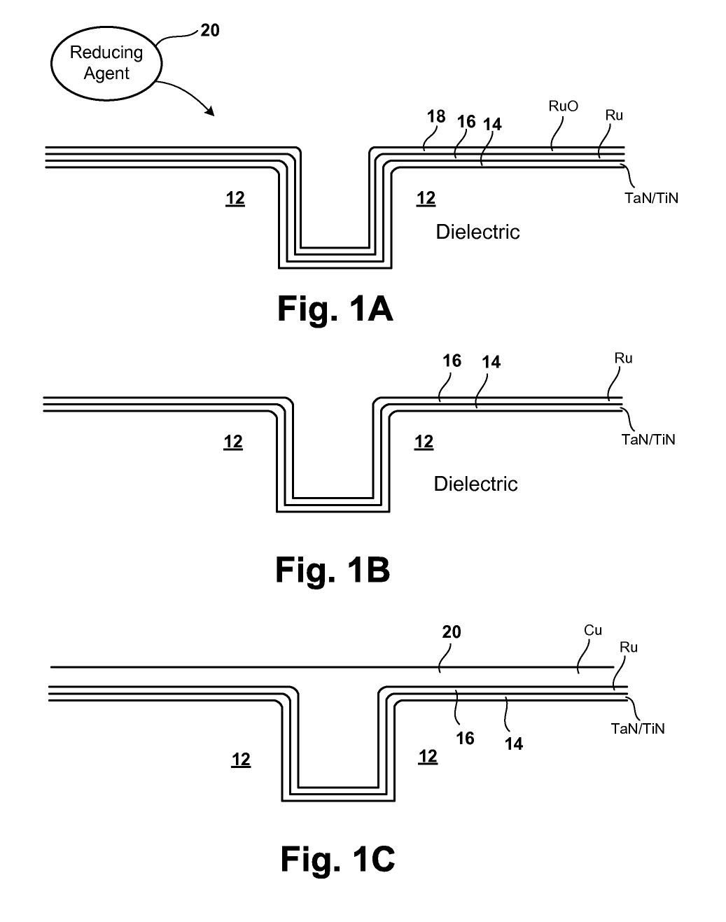

FIG. 1A illustrates a cross-section view of a portion of a substrate 10 following ruthenium deposition, in accordance with an embodiment of the invention. As shown, the substrate includes a dielectric region 12, which can be composed of any of various dielectric materials as are known in the art. Typical dielectric materials include silicon dioxide, as well as various oxides, nitrides, and other dielectric compositions, and may be carbon-doped, porous, or otherwise configured to provide suitable dielectric properties for the substrate's application. As ruthenium does not adhere well to typical dielectric materials, a barrier layer 14 is first deposited onto the dielectric 12, followed by deposition of the ruthenium layer 16 over the barrier layer 14. Thus, the barrier layer 14 acts as an adhesion layer between the ruthenium layer 16 and the dielectric 12.

In some embodiments, the barrier layer 14 can include tantalum nitride (TaN), titanium nitride (TiN), or other barrier materials which exhibit adequate adhesion to both the dielectric and to ruthenium. In some embodiments, the total thickness of the barrier layer 14 is built up through repeated deposition operations to deposit a series of sub-layers that together form the entire barrier layer 14. In some embodiments, as the sub-layers of the barrier layer are deposited, ruthenium is gradually mixed with the barrier layer material (e.g. TaN or TiN) in increasing relative amounts. This produces a gradient of ruthenium in the barrier layer 14, such that little or no ruthenium is present near the interface with the dielectric 12, whereas higher concentrations of ruthenium are present in portions of the barrier layer 14 situated away from the interface with the dielectric.

As with the barrier layer 14, the ruthenium layer 16 deposited over the barrier layer 14 can be deposited through a series of repeated deposition operations. This builds up the thickness of the ruthenium layer 16 through deposition of sub-layers of ruthenium. The ruthenium layer 16 adheres to the barrier layer 14, which in turn adheres to the dielectric 12. In this manner, though ruthenium does not directly adhere well to the dielectric 12, ruthenium can be deposited over the barrier layer 14 which serves as an intermediary enabling adhesion to the dielectric 12.

After deposition of the ruthenium layer 16, the ruthenium surface may become oxidized upon air and humidity exposure, such that ruthenium oxide 18 is present on the exposed surface of the ruthenium layer 16. It is important to remove this ruthenium oxide, as it prevents deposition of copper over the ruthenium. Therefore, it is desirable to reduce the ruthenium oxide to ruthenium by the application of a reducing agent 20. FIG. 1B illustrates the substrate following application of the reducing agent 20 to reduce the ruthenium oxide to ruthenium. As shown, the surface of the substrate is defined by an exposed surface of the pure ruthenium layer 16, free of contaminating oxides which inhibit copper adhesion.

After reduction of the surface ruthenium oxides to ruthenium, a copper layer 20 is deposited over the ruthenium layer 16 by any of various methods, including wet electroless deposition as well as dry vapor deposition methods. FIG. 1C illustrates the substrate after deposition of a copper layer 20 over the ruthenium layer 16 has taken place.

As can be seen, reduction of the ruthenium surface to eliminate oxidation is important to enable subsequent deposition of copper over the ruthenium. A dry pretreatment reduction may employ a forming gas anneal at temperatures in the range of 250-300 degrees Celsius for about three to five minutes. However, the high temperatures employed also necessitate a subsequent cool-down period, during which reoxidation may occur. The length of time required for such a reduction process from start to finish is therefore not only prohibitive as it may reduce throughput, but also adversely impacts the reduction efficiency due to the possibility of reoxidation.

Several possible wet reduction pretreatments utilizing common reducing agents are also fraught with issues that make them unsatisfactory for production processes. For example one possible reducing agent that can be applied to reduce the ruthenium surface in a wet process is dimethylamineborane (DMAB). However, byproducts of the reduction process employing DMAB can attach to the Ru surface. Such byproducts will weaken the interface between the ruthenium layer and subsequently deposited copper. Additionally, DMAB solutions exhibit a high degree of instability, tending to spontaneously evolve hydrogen, which presents challenges when scaling to a production level process. Solution instability results in a low effective shelf life for DMAB solutions, which consequently require more frequent changing or replenishment. This necessitates additional oversight and causes increased process tool downtime, which ultimately reduces throughput and increases the cost of using DMAB as a reducing agent.

Another example of a reducing agent that can be utilized in a wet pretreatment reduction process is ammonia borane. However, as with DMAB, ammonia borane solutions also tend to exhibit a high degree of instability that results in low shelf life. Again, this drives up the cost of using ammonia borane as a reducing agent for reducing ruthenium surfaces in a production environment. In sum, commonly applied wet pretreatments for reduction purposes are generally not amenable to transport due to hydrogen evolution that results in low shelf life.

In view of these problems with commonly applied reducing agents, a method for reducing ruthenium oxide present on a ruthenium surface is herein described that provides a stable solution and long chemical shelf life. Broadly speaking, the method utilizes borohydride as a reducing agent. A concentrated borohydride solution is prepared with pH adjusted to be greater than about 12. The resulting concentrated solution is stable, exhibiting long shelf life, and can be diluted at the point of use just prior to application on the surface of a substrate.

Borohydrides have been utilized in fuel cell manufacturing to generate hydrogen. However, borohydrides are unstable in water, as they evolve hydrogen over time. It has been found that borohydrides can be stabilized by configuring the solution to be alkaline In an article entitled “An Ultrasafe Hydrogen Generator: Aqueous, Alkaline Borohydride Solutions and Ru Catalyst,” published in Journal of Power Sources, Volume 85, Issue 2, February 2000, pages 186-189, (the disclosure of which is incorporated by reference herein), Amendola et al. describe an alkaline borohydride solution that produces hydrogen when in the presence of a metal catalyst. When hydrogen gas is no longer required, the metal catalyst is removed from the solution and the hydrogen generation effectively stops. Additionally, Amendola et al. observed zero order kinetics for NaBH₄ hydrolysis at NaBH₄ concentrations as low as 0.1%.

In an article entitled “Stability of Aqueous-Alkaline Sodium Borohydride Formulations,” published in the Russian Journal of Applied Chemistry, Vol. 81, No. 3, 2000, pages 380-385, (the disclosure of which is incorporated by reference herein) Minkina et al. explore the stability of sodium borohydride in concentrated solutions, suspensions, and solids, including the effects of temperature, concentrations of sodium borohydride and alkali, and the nature of the alkali metal cation on the rate of sodium borohydride hydrolysis. Minkina et al. observed in systems containing sodium borohydride, alkali, and water, a rate of hydrolysis not exceeding 0.02% NaBH₄ per hour at temperatures of up to 30 degrees Celsius, with increases in temperature significantly accelerating the rate of hydrolysis. Minkina et al. further state that for storage at temperatures above 30 degrees Celsius, it is necessary to add alkali in a concentration higher than 5 wt %.

As has been shown, borohydride solutions can be stabilized when adjusted to alkaline pH. In accordance with embodiments of the invention, this aspect of borohydride solutions can be leveraged to enable production-level semiconductor reduction processes. In one embodiment, a concentrated pretreatment solution includes about 0.5 to about 2.5 molar (M) borohydride in solution. The source of the borohydride can be any of various borohydride salts, including but not limited to, sodium borohydride, potassium borohydride, magnesium borohydride, calcium borohydride, lithium borohydride, tetramethylammonium borohydride, tetrabutylammonium borohydride, ammonium borohydride, etc. The pH of the concentrated pretreatment solution is adjusted to be greater than about 12 through the addition of an alkaline pH adjuster. The pH adjuster can be any of various bases, including sodium hydroxide (NaOH), potassium hydroxide (KOH), tetramethylammonium hydroxide (TMAH), tetraethylammonium hydroxide (TEAH), ammonium hydroxide (NH₄OH), etc. In embodiments of the invention, the molar concentration of hydroxide is approximately equivalent to the molar concentration of borohydride. By utilizing equivalent molar amounts, metallic precipitates are generally avoided.

Prior to application onto a ruthenium surface of a substrate, the concentrated pretreatment solution is diluted with deoxygenated DI water to form a working pretreatment solution having a borohydride concentration of about 50 to about 2500 millimolar (mM). In another embodiment, the working pretreatment solution has a borohydride concentration of about 20 to about 2500 mM. In one embodiment, the working pretreatment solution has a borohydride concentration of approximately 80 to about 200 mM. While specific ranges have been provided, it should be appreciated that these are provided by way of example only, and that in various embodiments, the borohydride concentration may have any subrange defined therein. As noted above, zero order reaction kinetics are observed with respect to borohydride down to very low concentrations. Thus, only a relatively small concentration of borohydride is required for purposes of effective ruthenium surface reduction. The pretreatment solution can therefore be kept in concentrated form, stabilized by the high pH, until it is required for use, at which time the concentrated solution can be diluted at the point of use with deoxygenated DI water and applied to the substrate's ruthenium surface.

This configuration effectively addresses many of the problems inherent to the use of unstable reducing agents such as borohydrides in a manufacturing process. In large part, unstable reducing agents are difficult to utilize in production processes due to their short shelf life and sensitivity to factors such as temperature. These characteristics mean that reducing agents must be manufactured, shipped, handled and used at their destination under stringent control parameters and all within a limited time frame. This creates difficulties in terms of supply logistics, as manufacturing processes are highly dependent on frequent and precisely timed shipments of reducing agents. Flexibility in terms of production capacity is thereby reduced. Throughput is also adversely affected due to the frequent need to take tools offline to replace supplies of the reducing agents.

However, in accordance with embodiments of the invention described herein, a stable concentrated solution of borohydride is provided as a reducing agent source for a pretreatment operation for a ruthenium surface. The stable concentrated solution of borohydride can be shipped under a variety of conditions and exhibits a long shelf life that makes it better-suited to production manufacturing processes. The longer shelf life of the stabilized concentrated solution means that it can be used for a longer period of time before needing replacement. The result is increased throughput as the tool incurs less downtime from replacement of the concentrated solution.

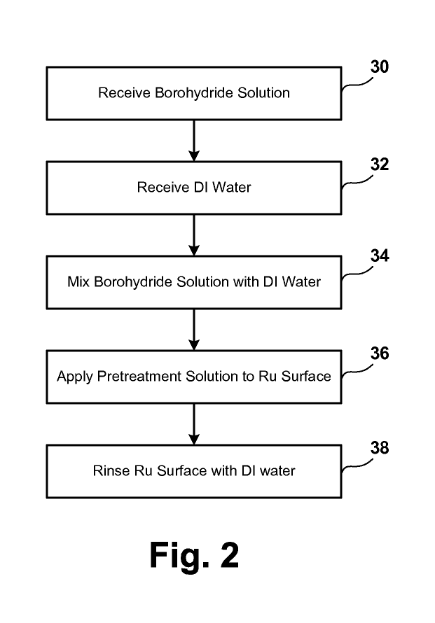

FIG. 2 illustrates a method for preparing a ruthenium surface for metal deposition, in accordance with an embodiment of the invention. At method operation 30, the method initiates with receiving a borohydride solution having a pH greater than about 12. At method operation 32, degassed deionized (DI) water is received. Degassed DI water is effectively deoxygenated, and may have very low levels of oxygen, e.g. approximately less than 5 parts per billion (ppb). At method operation 34, the borohydride solution is mixed with the DI water to form a pretreatment solution. At method operation 36, the pretreatment solution is applied to the ruthenium surface. At method operation 38, after the pretreatment solution has been applied, the ruthenium surface is rinsed with DI water.

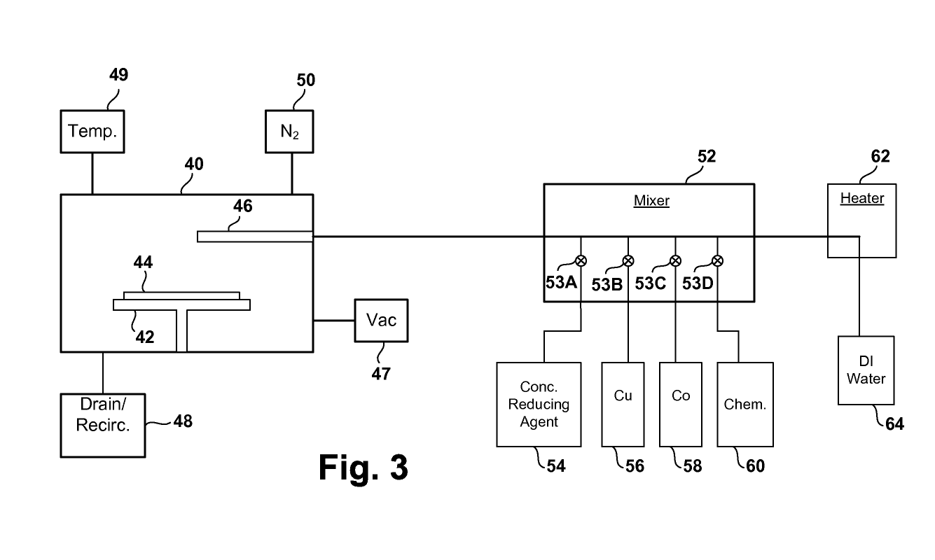

FIG. 3 illustrates a system for performing wet processing of a substrate, in accordance with an embodiment of the invention. A chamber 40 is provided, in which a controlled environment is maintained. The chamber 40 includes a support 42 for supporting a substrate 44. The support 42 can be configured to rotate, and may also be configured to be heated/cooled. An inert gas source 50 supplies an inert gas, such as nitrogen, to the chamber 40. A vacuum source 47 applies a vacuum to the chamber 40 to exhaust gas from the chamber 40. A drain module 48 removes liquid from the chamber 40, and may be optionally configured to recirculate liquid that may be reused. A temperature controller 49 controls the internal temperature of the chamber 40 at predefined levels.

A mixer 52 is provided for mixing various solutions with a DI water stream provided by a DI water source 64. The DI water and any solutions which have been mixed therewith are flowed into the chamber 40 and dispensed from a dispense head 46 onto the surface of the substrate 44. A heater 62 can be applied to heat the DI water to a predefined temperature. It will be appreciated that any of various types of solutions can be provided for use with the presently described wet process system. By way of example, in the illustrated embodiment, a concentrated reducing agent solution 54 is provided for pretreatment reduction of the substrate 44 prior to metal deposition. The concentrated reducing agent solution 54 can define a concentrated pretreatment solution that is diluted via mixing with the DI water stream to define a working pretreatment solution that is applied to reduce a ruthenium containing surface of a substrate.

In the illustrated embodiment, a copper deposition solution 56 and a cobalt deposition solution 58 are also shown. A solution 60 can be any of various other solutions useful for wet processing of a substrate. It will be appreciated that in various embodiments, any number of solutions may be configured to operate with the presently described wet processing system.

In one embodiment, the mixer 52 includes various valves 53A, 53B, 53C, and 53D for controlling the flow of the various solutions 54, 56, 58, and 60 into the DI water stream. For example, when all valves are closed, the DI water stream is supplied to the chamber 40 and flowed onto the substrate 44 without additives, acting as a DI water rinse. When, for example, the valve 53A is opened, then the concentrated pretreatment solution 54 is mixed with the DI water stream to define a working pretreatment solution that is then applied to the substrate 44. When the valve 53A is closed, then the DI water stream continues to flow without the addition of other solutions and is applied to the substrate, again acting as a DI water rinse. In a similar manner, when any of the valves 53B, 53C, or 53D is opened, its corresponding solutions is mixed with the DI water stream, effectively being diluted via the mixing to a working concentration level, with the working solution then being applied to the substrate 44. When the valve is closed, the flow of the concentrated solution is stopped, effectively returning the applied solution to a pure DI water state that then acts to rinse the substrate surface. Thus, the opening and closing of the valves of the mixer 52 can be controlled to define various process operations, by controlling periods of DI water application and working solution application onto the substrate surface.

It will be appreciated that the operation of the various components of the illustrated system can be controlled by one or more programmable controllers, which may be configured to enable execution of a sequence of processing operations utilizing the aforementioned system components, in accordance with principles of the invention as described herein.

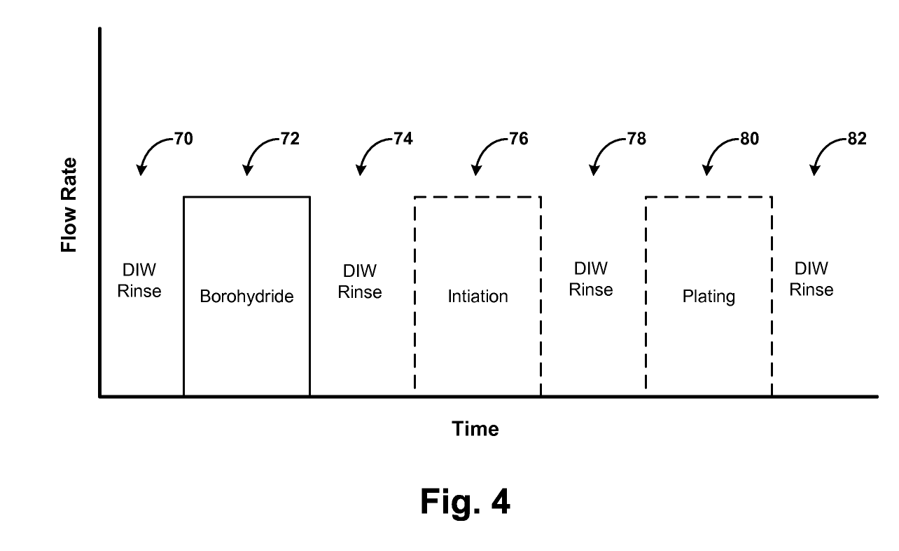

FIG. 4 is a graph illustrating the flow of various liquids during reduction and plating processes, in accordance with an embodiment of the invention. The graph conceptually illustrates the introduction of various solutions into a DI water stream, in accordance with the apparatus of FIG. 3. The DI water stream is constantly flowing onto the substrate. Therefore, when no solutions are mixed into the DI water stream, the DI water stream acts to rinse the surface of the substrate of any previously introduced solutions and also maintain the surface of the substrate in a wet state. The graph shown at FIG. 4 illustrates flow rate vs. time for the various solutions utilized in a reduction and plating process. During a time period 70, no solutions are mixed into the DI water stream, and hence a DI water rinse occurs. During a subsequent time period 72, a borohydride solution is mixed with the DI water stream. As shown in the illustrated graph, the flow rate of the borohydride solution increases abruptly and plateaus at a constant rate. The mixture of the borohydride solution with the DI water effectively dilutes the borohydride solution to working levels, as are described elsewhere herein. The borohydride mixture is flowed onto the substrate surface effecting a reduction step in which the ruthenium surface of the substrate is reduced. When the borohydride flow is stopped, then at time 74, the DI water stream continues to flow and thus acts to rinse the surface of the substrate, defining a rinse step.

At time 76, a plating initiation solution is mixed with the DI water stream, thereby defining an initiation step as the substrate surface is exposed to the mixed initiation solution and DI water. When the flow of the plating initiation solution is stopped, then at time 78, a DI water rinse step is effected. At time 80, a copper plating solution is mixed with the DI water stream so as to effect plating of copper onto the substrate surface, thus defining a copper plating step. At time 82, the flow of the copper plating solution has been stopped, resulting in a subsequent DI water rinse step.

The foregoing embodiment includes the introduction of an initiation step and subsequent DI water rinse. However, it should be noted that in some embodiments, these steps are not included. In such embodiments, the reduction step is followed by a DI water rinse and then copper plating.

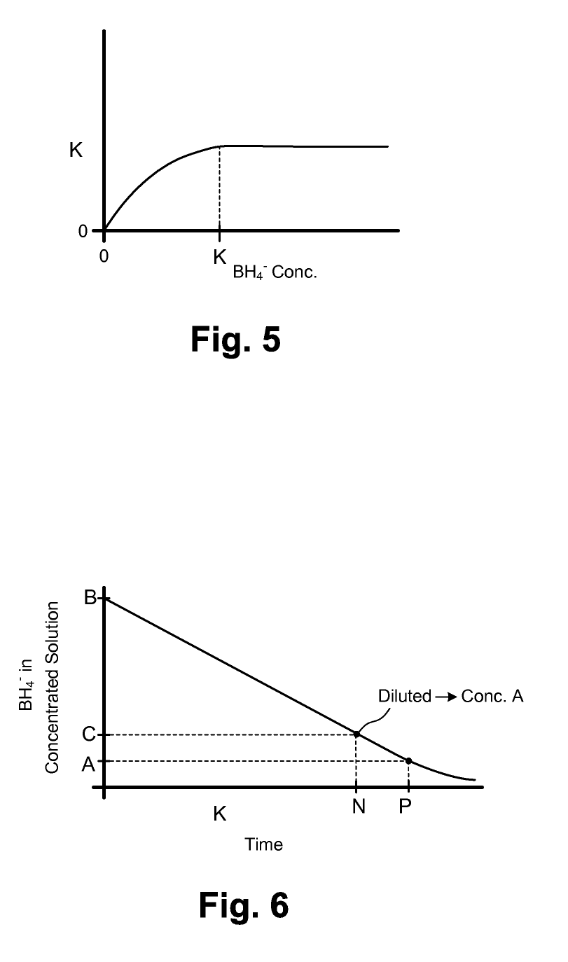

FIG. 5 is a graph conceptually illustrating the rate of borohydride hydrolysis in the presence of Ru as a function of borohydride concentration, in accordance with an embodiment of the invention. At low borohydride concentrations, approximately below a concentration A in the illustrated graph, it is believed that diffusion controlled first-order reaction kinetics dominate. However, at higher concentrations, approximately above the concentration A in the illustrated graph, the rate of hydrolysis exhibits zero-order reaction kinetics, such that the reaction rate is independent of borohydride concentration. In the illustrated graph, the rate of hydrolysis is approximately constant when the borohydride concentration is approximately above the concentration A.

FIG. 6 is a graph conceptually illustrating the concentration of borohydride in a concentrated pretreatment solution over time, in accordance with an embodiment of the invention. As shown, the concentration of borohydride in the concentrated solution is initially at a concentration B, and gradually reduces over time in an approximately linear fashion. In other words, the rate of hydrolysis of borohydride is approximately constant. When the concentration of borohydride drops to approximately a concentration C, this concentration C corresponds to a working concentration (resulting from dilution of the concentrated pretreatment solution to a working pretreatment solution at a given dilution ratio) equivalent to the concentration A as discussed above with reference to FIG. 5. In other words, when the concentration of borohydride in the concentrated pretreatment solution drops below approximately concentration C, then in the (diluted) working pretreatment solution, the reduction reaction rate will cease to exhibit zero order kinetics with respect to borohydride concentration. Thus, when the concentration of the concentrated borohydride solution diminishes to approximately the concentration C, further reductions in the borohydride concentration may result in lowered reaction rates. And hence, it may be desireable at or near this level, which corresponds to an approximate time N (duration that the concentrated pretreatment solution is in use), to replace the concentrated pretreatment solution with fresh concentrated pretreatment solution having the initial concentration B of borohydride.

In the presently described embodiment, the dilution of the concentrated pretreatment solution with DI water occurs at a fixed ratio for a specific duration over which the working concentration of borohydride is effective for achieving an acceptable reaction rate. In other words, the ratio of concentrated pretreatment solution to DI water remains constant, and the concentrated pretreatment solution is periodically replaced when its borohydride concentration falls to a level below which the working solution would no longer be suitably effective. In the foregoing embodiment, this level is the concentration C which occurs at approximately time N.

However, it will be appreciated that the borohydride concentration of the concentrated pretreatment solution does not fall to the concentration A until a later time P. Furthermore, because zero order kinetics are exhibited with respect to borohydride concentration above concentration A, there is little or no benefit to the rate of reaction at higher concentrations of borohydride in the working pretreatment solution. In view of these aspects, and in order to conserve the concentrated pretreatment solution and extend its usable lifetime, it may be desirable to vary its dilution ratio with respect to DI water.

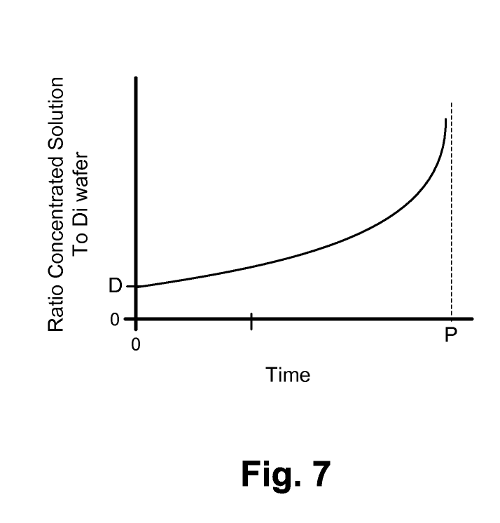

FIG. 7 is a graph illustrating adjustment of the dilution ratio of concentrated pretreatment solution to DI water over time, in accordance with an embodiment of the invention. Initially, the concentrated pretreatment solution is diluted with DI water at a ratio D. Over time, the ratio increases to compensate for the decreasing borohydride concentration of the concentrated pretreatment solution, and approaches infinity (100% concentrated pretreatment solution and no DI water) at the time P, which is the time at which the concentrated pretreatment solution exhibits the borohydride concentration A. In one embodiment, the adjustment of the dilution ratio of concentrated pretreatment solution to DI water over time is configured to maintain a working concentration A of borohydride in the diluted working pretreatment solution. In this manner, the working pretreatment solution will provide for a maximum or near-maximum reaction rate while utilizing a minimal amount of the concentrated pretreatment solution.

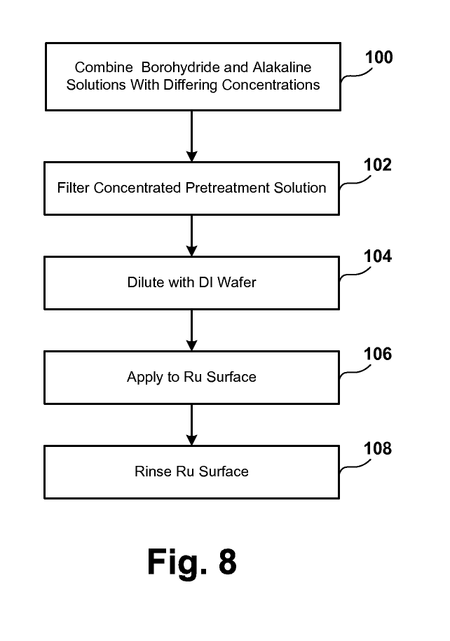

Embodiments of the invention have generally been described with reference to pretreatment solutions having approximately equal molar amounts of borohydride and alkaline components. However, in other embodiments, the pretreatment solution can be configured to have different molar amounts of borohydride and alkaline components. FIG. 8 illustrates a method for utilizing a pretreatment solution having non-matching molar concentrations of borohydride and alkaline salts, in accordance with an embodiment of the invention. At method operation 100, a borohydride solution and an alkaline solution are combined to form a concentrated pretreatment solution having non-equal molar concentrations of borohydride and a basic salt. By way of example, in one embodiment, the concentration of borohydride is approximately in the range of about 1M to about 5M, whereas the concentration of the base is approximately 0.5M greater than that of the borohydride concentration, in the range of 1.5M to 5.5M. In one specific embodiment, the concentration of the borohydride is approximately 2.0M and the concentration of the base is approximately 2.5M. By creating a concentrated pretreatment solution with non-equal molarities of the borohydride and base components, the solution will tend to precipitate out metallic impurities. Thus, at operation 102, the concentrated pretreatment solution is filtered to remove the precipitated metallic impurities. By formulating the concentrated pretreatment solution with a mismatch in the concentration of borohydride and basic components, this affords the opportunity to purify the concentrated pretreatment solution prior to use. At operation 104, the concentrated pretreatment solution is diluted with DI water to form a working pretreatment solution. At operation 106, the working pretreatment solution is applied to the ruthenium containing surface of a substrate for a predefined period of time. At operation 108, the surface of the substrate is rinsed with DI water.

Embodiments of the invention have been described utilizing borohydride as a reducing agent. However, in other embodiments, boranes are utilized as reducing agents in a similar manner. For example, a concentrated pretreatment solution may have a borane concentration of approximately 0.75 to 1M borane, with a pH adjusted to be greater than about 12. The borane source can be DMAB, ammonia borane, etc., and the pH adjuster can be NaOH, KOH, TMAH, TEAH, NH₄OH, etc.

While this invention has been described in terms of several preferred embodiments, it will be appreciated that those skilled in the art upon reading the preceding specifications and studying the drawings will realize various alterations, additions, permutations and equivalents thereof. It is therefore intended that the present invention includes all such alterations, additions, permutations, and equivalents as fall within the true spirit and scope of the invention.

What is claimed is:

1. A wet pretreatment method for preparing a ruthenium surface for metal deposition, comprising:
receiving a borohydride solution having a pH greater than about 12;
receiving deionized (DI) water;
mixing the borohydride solution with the DI water to form a pretreatment solution;
applying the pretreatment solution to the ruthenium surface.

2. The method of claim 1, further comprising, after applying the pretreatment solution, rinsing the ruthenium surface with DI water.

3. The method of claim 1,
wherein the borohydride solution includes a base selected from the group consisting of sodium hydroxide, potassium hydroxide, ammonium hydroxide, trimethylammonium hydroxide, triethylammonium hydroxide.

4. The method of claim 3, wherein the borohydride solution has a borohydride concentration approximately equal to a concentration of the base.

5. The method of claim 1, wherein the borohydride solution has a borohydride concentration of about 0.5 to 2.5 M.

6. The method of claim 1, wherein the pretreatment solution has a borohydride concentration of about 50 to about 2500 mM.

7. The method of claim 1, wherein the DI water is degassed DI water having an oxygen concentration of less than about 5 ppb.

8. The method of claim 1, wherein the method is used to perform at least one operation in the fabrication of an integrated circuit.

9. A wet pretreatment method for preparing a ruthenium surface for metal deposition, comprising:
applying a stream of DI water onto a ruthenium surface;
mixing a borohydride solution into the stream of DI water, the borohydride solution having a pH greater than 12 prior to the mixing;
after a predefined period of time, halting the mixing of the borohydride solution into the stream of DI water.

10. The method of claim 9,
wherein the mixing of the borohydrde solution into the stream of DI water defines a pretreatment operation; and
wherein the halting of the mixing of the borohydride solution into the stream of DI water defines initiation of a rinse operation.

11. The method of claim 9,
wherein the borohydride solution includes a base selected from the group consisting of sodium hydroxide, potassium hydroxide, ammonium hydroxide, trimethylammonium hydroxide, triethylammonium hydroxide.

12. The method of claim 11, wherein the borohydride solution has a borohydride concentration approximately equal to a concentration of the base.

13. The method of claim 9, wherein the borohydride solution has a borohydride concentration of about 0.5 to 2.5 M.

14. The method of claim 9, wherein the mixing of the borohydride solution into the DI water stream defines a pretreatment solution having a borohydride concentration of about 50 to about 2500 mM.

15. The method of claim 9, wherein the DI water is degassed DI water having an oxygen concentration of less than about 5 ppb.

16. The method of claim 9, further comprising, after the halting of the mixing of the borohydride solution into the DI water stream, mixing an electroless copper deposition solution into the DI water stream.

17. The method of claim 9, wherein the method is used to perform at least one operation in the fabrication of an integrated circuit.

18. A system for preparing a ruthenium surface of a wafer, comprising:
a chamber configured to support the wafer;
a DI water source;
a conduit for delivering a DI water stream from the DI water source to the chamber for application onto the ruthenium surface of the wafer;
a borohydride solution source containing a borohydride solution having a pH greater than 12;
a mixer for mixing the borohydride solution from the borohydride solution source into the DI water stream.

19. The system of claim 18, wherein the borohydride solution has a borohydride concentration of about 0.5 to 2.5 M.

20. The system of claim 18, wherein the mixing of the borohydride solution into the DI water stream defines a pretreatment solution having a borohydride concentration of about 50 to about 2500 mM.

21. The system of claim 18, further comprising, a controller configured to control the mixer to initiate the mixing of the borohydride solution into the DI water stream and terminate the mixing after a predefined time period has elapsed.

22. The system of claim 18, further comprising, an electroless copper deposition solution source;
a second mixer for mixing electroless copper deposition solution from the electroless copper deposition solution source into the DI water stream.

23. The system of claim 18, wherein the system is configured to perform at least one operation in the fabrication of an integrated circuit.
